(19) United States
(12) Patent Application Publication
(10) Pub. No.: US 2015/0014728 A1
(43) Pub. Date: Jan. 15, 2015

(54) Phosphor-matrix composite powder for minimizing light scattering and led structure including the same

(71) Applicant: KOOKMIN UNIVERSITY INDUSTRY ACADEMY COOPERATION FOUNDATION, Seoul (KR)

(72) Inventor: Young-Rag Do, Seoul (KR)

(73) Assignee: KOOKMIN UNIVERSITY INDUSTRY ACADEMY COOPERATION FOUNDATION, Seoul (KR)

(21) Appl. No.: 14/375,789

(22) PCT Filed: Jan. 29, 2013
(86) PCT No.: PCT/KR2013/000707

§ 371 Date: Jul. 30, 2014

(30) Foreign Application Priority Data
Jan. 30, 2012 (KR) 10-2012-0009048

(51) Int. Cl. H01L 33/50; C09K 11/02

(52) U.S. Cl. CPC H01L 33/502; C09K 11/025
USPC 257/98; 252/301.4 R; 428/402; 252/301.4 F; 252/301.36; 252/301.6 S

(57) ABSTRACT

This invention relates to a phosphor-matrix composite powder for minimizing light scattering and to an LED structure including the same, wherein the phosphor-matrix composite powder satisfying certain relation is prepared and the LED structure including the same is manufactured, thus minimizing light scattering and reflection and maximizing package efficiency.

### BACKGROUND OF THE INVENTION

1. Field of the Invention

The present invention relates to a phosphor-matrix composite powder for minimizing light scattering and an LED stricture including the same, and more particularly, to a phosphor-matrix composite powder for minimizing light scattering and an LED structure including the same, wherein the phosphor-matrix composite powder satisfies certain relation, thus minimizing light scattering and reflection and maximizing package efficiency.

2. Description of the Related Art

Among methods of manufacturing white LEDs known to date, the easiest method is a white phosphor-converted LED (pc-LED) method including applying a Y₃Al₅O₁₂:Ce³⁺ (YAG:Ce) phosphor on a blue InGaN LED chip to combine blue light passed through the phosphor with yellow light emitted from the phosphor to form white light.

The white pc-LED was first manufactured by applying a mixture of a YAG:Ce yellow powder phosphor and a silicone binder on an LED chip. Recently, to increase a color rendering index and easily adjust the color temperature, green and red powder phosphors instead of yellow are applied, so that a white color is obtained by the three colors: blue, green and red. Micro-sized powder phosphor has been utilized until now to manufacture the white pc-LED, but powder phosphor is disadvantageous because light conversion efficiency from blue excited light to light emitted from the phosphor is remarkably decreased due to loss of emitted light and loss of excited light by scattering/reflection loss.

Specifically, to evaluate the light conversion loss by the pc-LED, the light conversion efficiency may be represented by Relation 1 below.

<Relation 1>

Light conversion efficiency=photon quantity of light emitted from phosphor/photon quantity of blue light consumed by LED

In Relation 1, the photon quantity of blue light consumed by an LED is determined by subtracting the photon quantity of transmitted blue light remaining after consumption by the LED from the blue photon quantity emitted from the blue LED. FIG. 1 is a graph illustrating the light emission spectrum of the blue LED and the white LED, and the light conversion efficiency may be easily determined from the light emission spectrum of the blue LED and the light emission spectrum of the white LED made using the blue LED (light conversion efficiency=photon quantity of yellow light of white LED/(total photon quantity of blue LED−photon quantity of blue transmitted light of white LED)).

For the white LED using a currently available power chip, the light conversion efficiency may be approximately 58% at 350 mA (rated current). The light conversion efficiency may be represented by Relation 2 below, depending on the deterioration factors.

<Relation 2>

Light conversion efficiency=internal quantum efficiency of phosphor×LED package efficiency

In Relation 2, the low LED package efficiency may be caused by loss due to scattering/reflection and loss due to low light extraction. For the power chip white LED coated with the YAG:Ce powder phosphor, the light conversion efficiency is 0.55. As such, the internal quantum efficiency of the YAG:Ce powder phosphor is about 0.88. In Relation 2, the package efficiency is about 0.66 (66%), and thus a considerably large amount of light is lost due to scattering/reflection and low light extraction in the course of conversion from blue to yellow; and for the powder phosphor, light is mainly lost by scattering/reflection. Assuming that light loss due to scattering/reflection is completely removed, the light conversion efficiency is theoretically considered to be increased by about 51% compared to conventional phosphors. Although the conventional powder phosphor is relatively large in the amount of scattering loss, it is currently useful for white pc-LEDs because of its advantages including easy mass production, easy application to LEDs and high internal quantum efficiency. However, in order to solve problems of the considerably large efficiency loss due to scattering/reflection, research and development is ongoing into nanophosphors and transparent ceramic plate phosphors, in lieu of conventional powder phosphor, as novel technologies wherein scattering seldom occurs.

Based on the Mie scattering principle, when the size of the nanophosphors is 50 nm or less, the scattering loss of visible light disappears. Accordingly, a variety of methods of synthesizing nanophosphors from an light conversion phosphor such as YAG:Ce are under study. However, application of the nanophosphors to LEDs may incur another problem. Specifically, when nanophosphors are mixed with a conventional silicone or polymer binder, the nanophosphors may aggregate and may thus cause secondary scattering, undesirably resulting in light loss. Furthermore, for YAG:Ce nanophosphors developed to date, the internal quantum efficiency is about 60% which is evaluated to be much lower than that of conventional powder phosphors.

Despite such drawbacks, thorough research is being carried out into nanophosphors and phosphor films with the expectation that the quantum efficiency of nanophosphors will be increased as high as that of the conventional powder phosphor and that a transparent nanophosphor/matrix composite film will be developed to reduce scattering loss. However, the nanophosphor/matrix composite film may still cause light extraction loss due to a wave-guiding effect as a total reflection phenomenon which deteriorates light extraction efficiency. Hence, a novel light extraction structure has to be devised. Accordingly, in order to replace the conventional micro-sized powder phosphor with nanophosphor, there is a need for more specific efforts for resolving problems of low internal quantum efficiency, deteriorated scattering due to secondary aggregation and low light extraction efficiency of the nanophosphor/matrix composite film.

### SUMMARY OF THE INVENTION

Therefore, the present invention has been made keeping in mind the problems encountered in the prior art, and an object of the present invention is to provide a phosphor-matrix composite powder and an LED structure including the same, wherein the phosphor-matrix composite powder satisfying certain relation is prepared and the LED structure including the same is manufactured, thus minimizing light scattering and reflection and maximizing package efficiency.

In order to accomplish the above object, the present invention provides a phosphor-matrix composite powder for minimizing light scattering, comprising a matrix and a plurality of phosphors or quantum dots having a size of 100 nm or less dispersed in the matrix, wherein the composite satisfies Relation 3 below and is used as a light source for absorbing blue or near-ultraviolet light to emit visible light:

<Relation 3>

a) Composite size ≧20 μm; and

b) Surface root-mean-square-roughness (R_{q}) of composite ≦50 nm.

In addition, the present invention provides a phosphor-matrix composite powder for minimizing light scattering, comprising a core layer comprising a matrix having a size of 20 μm or more and a shell layer comprising a plurality of phosphors or quantum dots having a size of 100 nm or less, wherein the composite satisfies Relation 3 below and is used as a light source for absorbing blue or near-ultraviolet light to emit visible light:

<Relation 3>

a) Composite size ≧20 μm; and

b) Surface root-mean-square-roughness (R_{q}) of composite ≦50 nm.

Also, the composite powder may have a size of 30˜500 μm.

Also, the composite powder may have a spherical shape, a cylindrical shape or a cubic shape.

Also, the phosphors may comprise at least one selected from the group consisting of (YₓGd₁₋ₓ)₃(Al_{y}Ga_{1-y})₅O₁₂:Ce (x=0.0˜3.0, y=0.0˜5.0), (TbₓGd₁₋ₓ)₃(Al_{y}Ga_{1-y})₅O₁₂:Ce (x=0.0˜3.0, y=0.0˜5.0), Mg₃(YₓGd₁₋ₓ)₂Ge₃O₁₂:Ce (x=0.0˜2.0), CaSc₂O₄:Ce, Ca₃Sc₂Si₃O₁₂:Ce, (Srₓ,Ba_{y},Ca_{z})MgSi₂O₆:Eu,Mn (x, y, z=0.0˜1.0, x+y+z=1.0), (Srₓ,Ba_{y},Ca_{z})₃MgSi₂O₈:Eu,Mn (x, y, z=0.0˜3.0, x+y+z=3.0), (Srₓ,Ba_{y},Ca_{z})MgSiO₄:Eu,Mn (x, y, z=0.0˜1.0, x+y+z=1.0), Lu₂CaMg₂(Siₓ,Ge₁₋ₓ)₃O₁₂:Ce (x=0.0˜3.0), (Srₓ,Ba_{y},Ca_{z})₂SiO₄:Eu (x, y, z=0.0˜2.0, x+y+z=2.0), (Srₓ,Ba_{y},Ca_{z})₃SiO₅:Eu (x, y, z=0.0˜3.0, x+y+z=3.0), (Srₓ,Ba_{y},Ca_{z})₃SiO₅:Ce,Li (x, y, z=0.0˜3.0, x+y+z=3.0), Li₂SrSiO₄:Eu, LaSr₂AlO₅:Ce, Ca₂BO₃Cl:Eu, Y₃Mg₂AlSi₂O₁₂:Ce, BaMgAl₁₀O₁₇:Eu, Sr₂BaAlO₄F:Ce, (Srₓ,Ba_{y},Ca_{z})Ga₂S₄:Eu (x, y, z=0.0˜1.0, x+y+z=1.0), Ba₂ZnS₃:Ce,Eu, Ca₂SiS₄:Eu, Ca α-SiALON:Yb, Ca α-SiALON:Eu, α-SiALON:Yb, α-SiALON:Eu, Ca—Li-α-SiALON:Eu, β-SiALON:Eu, γ-AlON:Mn, γ-AlON:Mn,Mg, (Srₓ,Ba_{y},Ca_{z})₂Si₅N₈:Eu (x, y, z=0.0˜2.0, x+y+z=2.0), (Srₓ,Ba_{y},Ca_{z})Si₂O₂N₂:Eu (x, y, z=0.0˜1.0, x+y+z=1.0), CaₓAl₁₂(ON)₁₆:Eu, Ba₃Si₆O₁₂N₂:Eu, (Ba₁₋ₓSrₓ)_{Y}Si₄O₇:Eu (x=0.0˜1.0), (Ca₁₋ₓSrₓ)AlSiN₃:Eu (x=0.0˜1.0), and AlN:Eu.

Also, the composite powder may be transparent.

Also, the mixing ratio of the matrix and the phosphors may be 99.99:0.01˜50:50 by mass.

Also, the matrix may comprise a transparent material having a high refractive index.

Also, the matrix may be alumina, silicate. TiO₂, HfO₂, CeO₂, Y₂O₃, Gd₂O₃ or a silicone-based resin.

Also, the quantum dots may comprise at least one selected from the group consisting of CdSe/ZnS, CuInS₂/ZnS, Cu₂In₅S₈/ZnS, AgInS₂/ZnS, Ag₂In₅S₈/ZnS, and InP/ZnS.

Also, the composite may be an organic dye-linked organic-inorganic nanocomposite.

Also, the organic dye-linked organic-inorganic nanocomposite may be an organic dye-bridged organic-inorganic nanocomposite.

Also, the organic dye-bridged organic-inorganic nanocomposite may be prepared by subjecting a red dye- or green dye-bridged alkoxysilane-based nanocomposite to a sol-gel reaction to prepare an oligosiloxane composite which then undergoes a condensation reaction.

Also, the shell layer may have a thickness of 5˜100 nm.

In addition, the present invention provides an LED structure, comprising a blue or near-ultraviolet LED and the aforementioned composite bonded thereto.

According to the present invention, a phosphor-matrix composite powder and an LED structure including the same can minimize light scattering and reflection, thus exhibiting remarkably improved package efficiency compared to conventional powder phosphors, nano and ceramic plate phosphors, and phosphor-matrix composites.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a graph illustrating the light emission spectrum of a blue LED and a white LED;

FIG. 2 is a graph illustrating the phosphor size versus the scattering coefficient based on the Mie scattering principle;

FIG. 3 is a graph illustrating the surface root-mean-square roughness (R_{q}) of the phosphor versus the scattering coefficient based on the Mie scattering principle; and

FIGS. 4A and 4B are schematic views illustrating composites according to preferred embodiments of the present invention.

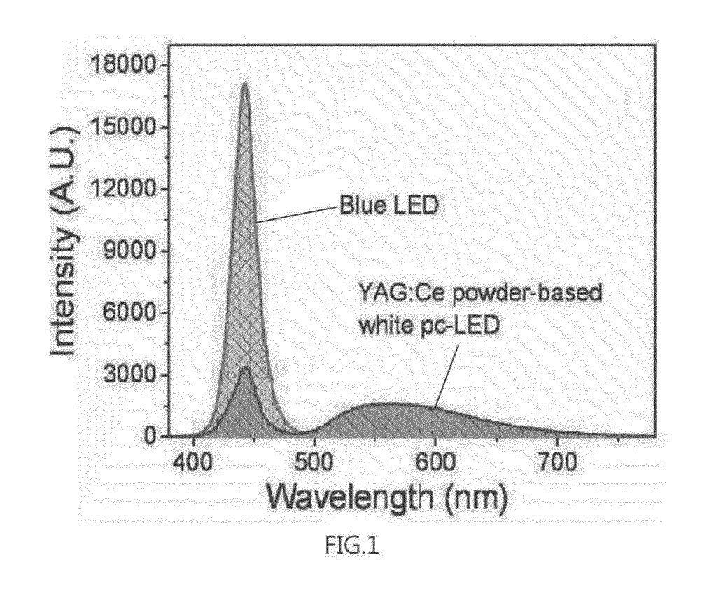

### DESCRIPTION OF SPECIFIC EMBODIMENTS

Hereinafter, a detailed description will be given of the present invention with reference to the appended drawings.

As mentioned above, when a conventional phosphor-matrix composite powder having high scattering loss is applied to LEDs, package efficiency may decrease, undesirably resulting in remarkably lowered light conversion efficiency.

Hence, an embodiment of the present invention addresses a phosphor-matrix composite powder for minimizing light scattering, which is configured such that a plurality of phosphors or quantum dots having a size of 100 nm or less is dispersed in a matrix, the composite satisfying Relation 3 below and being used as a light source for absorbing blue/near-ultraviolet light to emit visible light:

<Relation 3>

a) Composite size ≧20 μm; and

b) Surface root-mean-square-roughness (R_{q}) of composite ≦50 nm.

When manufacturing an LED including the composite satisfying the conditions a) and b) of Relation 3, light scattering and reflection may be minimized and package efficiency may be maximized.

Below is a description of a phosphor-matrix composite powder according to a first embodiment of the present invention.

The phosphor-matrix composite powder according to the first embodiment of the present invention is configured such that a plurality of phosphors or quantum dots having a size of 100 nm or less is dispersed in a matrix, and the composite powder satisfies the conditions of Relation 3. Specifically, the composite according to the present invention is applied to a phosphor useful as a light source for absorbing blue or near-ultraviolet light to emit visible light, and has to satisfy the conditions a) and b) of Relation 3.

The condition a) of Relation 3 is described below. As known in the art, to eliminate scattering of visible light, the phosphor size has to be decreased to 100 nm or less, and thus thorough research into nanophosphors is ongoing. In addition to the decrease in the phosphor size, scattering may be reduced based on the Mie scattering principle even when the size of a phosphor-matrix composite crystal is greater than that of a conventional composite.

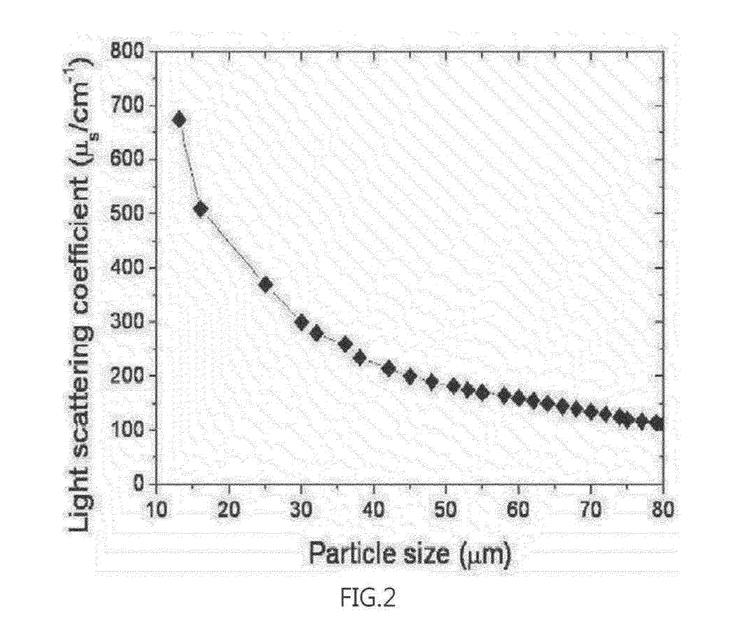

The phosphors and/or the quantum dots, which are dispersed in the matrix, have to have a size of 100 nm or less to minimize light scattering based on the Mie scattering principle. The composite powder comprising the phosphors and/or the quantum dots having a size of 100 nm or less should essentially satisfy Relation 3. In this regard, FIG. 2 is a graph illustrating the particle size versus the scattering coefficient based on the Mie scattering principle. Thus, when the particle size is at least 20 μm and preferably 30 μm or more, the scattering coefficient may be significantly lowered due to the crystal particles. A novel phosphor-matrix composite powder that is able to greatly lower the scattering loss should have a size of 50 nm or less or 20 μm or more based on the Mie scattering principle. When the size of the phosphor-matrix composite powder is 50 nm or less, internal quantum efficiency may decrease and light scattering may also be caused by secondary aggregation. Hence, in the present invention, the size of the phosphor-matrix composite powder has to be essentially set to 20 μm or more, and preferably 30˜500 μm.

Particularly, the size of the microsized phosphor-matrix composite powder for minimizing light scattering may be calculated by Relation 4 to 6 below.

<Relation 4>

Q=2−(4/ρ)sin+(4/ρ²)(1−cos ρ)

In this relation, ρ=2y((n₁/n₀)−1), y=2πan₀/λ, where n₁ and n₀ are the refractive indexes of a scattering body (phosphor-matrix composite) and a matrix, λ is the wavelength of incident light, a is the diameter (nm) of the scattering body (phosphor-matrix composite), and Q is the scattering efficiency.

The light scattering cross-section value of a particle is represented by σ of Relation 5 below.

<Relation 5>

σ=Q×A

In this relation, A is the geometric cross-section value of a scattering body (phosphor-matrix composite), and the calculated scattering coefficient μₛ is represented by Relation 6 below.

<Relation 6>

μₛ=s×D

In this relation, D is the number density of a scattering body.

In Relation 4 to 6 regarding the size of the composite powder versus the scattering coefficient, the phosphor-matrix composite having a size of at least 20 μm and preferably 30 μm or more may significantly reduce the scattering coefficient due to the crystal structure.

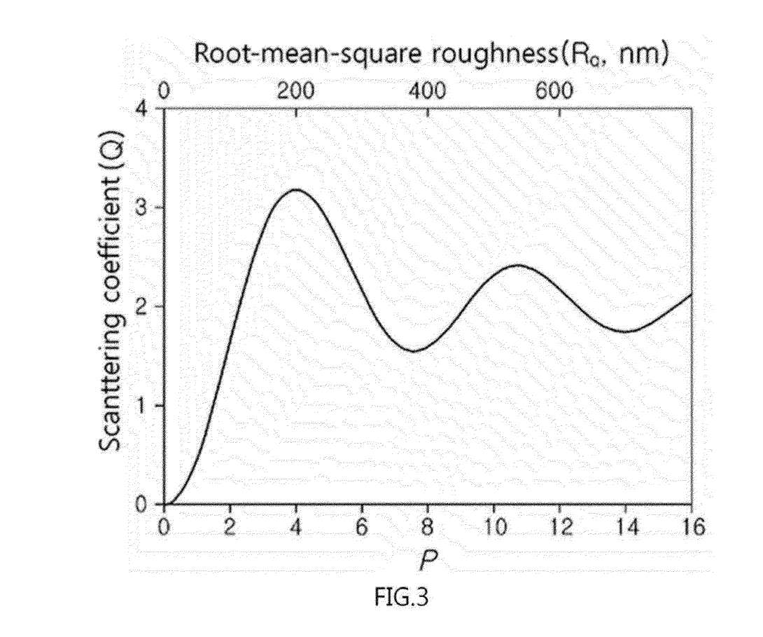

In addition to the condition a) of Relation 3, R_{q} of the composite corresponding to the condition b) of Relation 3 should be 50 nm or less. Specifically, FIG. 3 is a graph illustrating the R_{q} versus the scattering coefficient of the composite. When R_{q} is preferably 50 nm or less, the scattering coefficient may be remarkably decreased due to R_{q}.

R_{q} of the composite may be measured using a typical method, for example, a method disclosed in Korean Patent Application No. 2005-126461, but the present invention is not limited thereto.

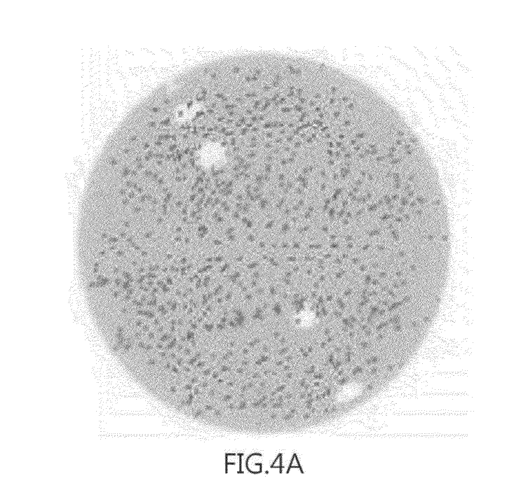

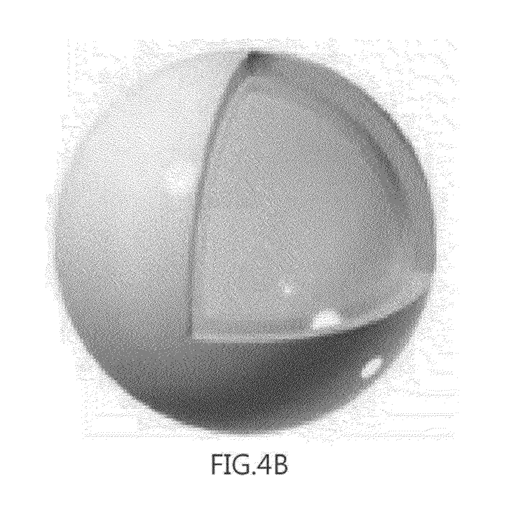

The inside and the surface of the composite may be variously formed so long as they satisfy the conditions of the crystal particles as mentioned above. Preferably, the composite may have a spherical shape of FIG. 4A or a cubic shape within a range satisfying the conditions of Relation 3, but the present invention is not limited thereto. Any composite satisfying Relation 3 may be incorporated into the scope of the present invention. FIG. 4A schematically illustrates a composite according to a preferred embodiment of the present invention, which is a spherical composite comprising a matrix and phosphors and/or quantum dots dispersed therein, or is an organic dye-linked organic-inorganic nanocomposite having a spherical shape.

Useful in the present invention, the composite may be a monocrystal-matrix composite or a polycrystal-matrix composite, within the range satisfying Relation 3. When the composite is a monocrystal-matrix composite, the composite comprises nano-sized monocrystals and the matrix. For the polycrystal-matrix composite, a plurality of polycrystal particles agglomerate with the matrix, thus forming a single structure. Thus, in the monocrystal-matrix composite or the polycrystal-matrix composite, the agglomerated composite is regarded as a single composite, and thus the size and the R_{q} thereof are determined. When the composite is the monocrystal-matrix composite or the polycrystal-matrix composite, the size of individual monocrystals or polycrystals thereof may be set to 100 nm or less to form a monocrystal or polycrystal composite. If the size of the individual monocrystals or polycrystals of the monocrystal-matrix composite or the polycrystal-matrix composite exceeds 100 nm, the scattering coefficient and scattering efficiency based on the Mie scattering principle may increase, undesirably increasing light emission loss of the composite and the blue excided light due to scattering of visible light. Furthermore, the polycrystal-matrix composite is very favorable in terms of minimizing scattering when the pore size defined by the individual polycrystals thereof is 50 nm or less.

Usable in the present invention, another composite may be an organic dye-linked organic-inorganic nanocomposite within the range satisfying Relation 3. The organic dye mainly includes organic molecules having a size of 10 nm or less as a small molecular material. When the composite is formed through bridging with oligosiloxane, light scattering does not occur and the organic-inorganic matrix formed by condensation is also transparent, thus causing no scattering. Thus, when the dye-bridged organic-inorganic matrix composite satisfies the conditions of Relation 3, scattering may be minimized.

As for the white pc-LED including the composite powder for minimizing scattering, the internal quantum efficiency (˜90%) of the phosphor is 70% or more when considering the quantum efficiency of a conventional composite, the results of minimized scattering/reflection loss may be applied to the light conversion efficiency, and thus not only the conventional powder phosphor but also the nanophosphor or the phosphor-matrix composite powder may be replaced.

Meanwhile, the present invention pertains not to chemical conditions but to physical conditions of the composite and the phosphors and/or quantum dots and the matrix contained therein. Therefore, any matrix may be used without particular limitation so long as it is used in the phosphor and the composite as the light source for absorbing blue or near-ultraviolet light to emit visible light.

The phosphors useful in the invention may include an inorganic phosphor, such as a YAG phosphor, an oxide, a nitride, an oxynitride, a sulfide, a rare earth acid sulfide, a halide, an aluminate chloride, a halophosphate chloride, etc.

Preferably, the phosphors include, but are not limited to, any one or more selected from the group consisting of (YₓGd₁₋ₓ)₃(Al_{y}Ga_{1-y})₅O₁₂:Ce (x=0.0˜3.0, y=0.0˜5.0), (TbₓGd₁₋ₓ)₃(Al_{y}Ga_{1-y})₅O₁₂:Ce (x=0.0˜3.0, y=0.0˜5.0), Mg₃(YₓGd₁₋ₓ)₂Ge₃O₁₂:Ce (x=0.0˜2.0), CaSc₂O₄:Ce, Ca₃Sc₂Si₃O₁₂:Ce, (Srₓ,Ba_{y},Ca_{z})MgSi₂O₆:Eu,Mn (x, y, z=0.0˜1.0, x+y+z=1.0), (Srₓ,Ba_{y},Ca_{z})₃MgSi₂O₈:Eu,Mn (x, y, z=0.0˜3.0, x+y+z=3.0), (Srₓ,Ba_{y},Ca_{z})MgSiO₄:Eu,Mn (x, y, z=0.0˜1.0, x+y+z=1.0), Lu₂CaMg₂(Siₓ,Ge₁₋ₓ)₃O₁₂:Ce (x=0.0˜3.0), (Srₓ,Ba_{y},Ca_{z})₂SiO₄:Eu (x, y, z=0.0˜2.0, x+y+z=2.0), (Srₓ,Ba_{y},Ca_{z})₃SiO₅:Eu (x, y, z=0.0˜3.0, x+y+z=3.0), (Srₓ,Ba_{y},Ca_{z})₃SiO₅:Ce,Li (x, y, z=0.0˜3.0, x+y+z=3.0), Li₂SrSiO₄:Eu, LaSr₂AlO₅:Ce, Ca₂BO₃Cl:Eu, Y₃Mg₂AlSi₂O₁₂:Ce, BaMgAl₁₀O₁₇:Eu, Sr₂BaAlO₄F:Ce, (Srₓ,Ba_{y},Ca_{z})Ga₂S₄:Eu (x, y, z=0.0˜1.0, x+y+z=1.0), Ba₂ZnS₃:Ce,Eu, Ca₂SiS₄:Eu, Ca α-SiALON:Yb, Ca α-SiALON:Eu, α-SiALON:Yb, α-SiALON:Eu, Ca—Li-α-SiALON:Eu, β-SiALON:Eu, γ-AlON:Mn, γ-AlON:Mn,Mg, (Srₓ,Ba_{y},Ca_{z})₂Si₅N₈:Eu (x, y, z=0.0˜2.0, x+y+z=2.0), (Srₓ,Ba_{y},Ca_{z})Si₂O₂N₂:Eu (x, y, z=0.0˜1.0, x+y+z=1.0), CaₓAl₁₂(ON)₁₆:Eu, Ba₃Si₆O₁₂N₂:Eu, (Ba₁₋ₓSrₓ)_{Y}Si₄O₇:Eu (x=0.0˜1.0), (Ca₁₋ₓSrₓ)AlSiN₃:Eu (x=0.0˜1.0), and AlN:Eu.

Also, the quantum dots may include, but are not limited to, any one or more selected from the group consisting of CdSe/ZnS, CuInS₂/Zns, Cu₂In₅S₈/ZnS, AgInS₂/ZnS, Ag₂In₅S₈/ZnS, and InP/ZnS.

The phosphors useful in the invention are preferably transparent in terms of minimizing light scattering.

Further, the matrix for the composite of the invention is described. The matrix is used to disperse the nanophosphors and the quantum dots therein so as to prevent a reduction in light emission through self-absorption of light emitted from the phosphors or the quantum dots. Also, it may play a role in dispersing the nanophosphors or the quantum dots so as not to form clusters at a size able to scatter light.

In the present invention, any matrix may be used without limitation so long as it is typically useful in the phosphor-matrix composite powder, and preferable examples thereof include, but are not limited to, transparent high-refractive materials, such as alumina, silicate, TiO₂, HfO₂, oligosiloxane, or mercer or silicone binders.

The energy conversion efficiency of the composite may vary depending on the kind or amount of the phosphor particles dispersed in the matrix. Specifically, when the amount of the phosphors and/or the quantum dots or the organic dye is excessively increased it is difficult to perform sintering, and porosity may increase, thus making it difficult to efficiently radiate excited light onto the phosphors or deteriorating mechanical strength of the composite. In contrast, when the amount of the above components is too low, it is difficult to achieve sufficient light emission. Thus, the mass ratio of the matrix to the phosphors is 99.99:0.01˜50:50, and preferably 99.95:0.05˜70:30, and more preferably 99.92:0.08˜85:15.

The composite powder according to the present invention may be obtained using a typical process for manufacturing a phosphor-matrix composite powder, and preferably a firing process or a curing process.

The composite thus manufactured is bonded to an LED having blue or near-ultraviolet light emission properties, thus forming a light emission device for converting wavelength. Compared to an LED using a conventional phosphor-matrix composite powder, the external quantum efficiency may be increased by 20% or more and the light emission efficiency of 50% or more may be achieved. Specifically, compared to the conventional phosphor-matrix composite powder, the internal quantum efficiency of only the phosphors is decreased by about 10˜156%, but the LED package efficiency including the phosphors according to the invention is increased by 20˜30% or more. Consequently, the external quantum efficiency of a white LED including the composite of the invention and the light emission efficiency expressed by lm/W may be greatly increased to 136˜148 lm/W from 114 lm/W.

In addition, a phosphor-matrix composite powder according to a second embodiment of the present invention is described.

According to the second embodiment of the present invention, the phosphor-matrix composite powder is configured to include a core layer comprising a matrix having a size of 20 μm or more and a shell layer comprising a plurality of phosphors or quantum dots having a size of 100 nm or less, and satisfies the conditions of Relation 3, as in the first embodiment.

Below, a description of the portions that overlap those of the first embodiment is omitted and the different portions are described.

Whereas the composite of the first embodiment is configured such that the phosphors and/or quantum dots are dispersed in the matrix as illustrated in FIG. 4A, the composite of the second embodiment has a core-shell structure configured such that, as illustrated in FIG. 4B, the surface of the matrix layer is covered with the phosphor layer (quantum dot- or dye-bridged organic-inorganic composite).

The matrix, phosphors and quantum dots used in the second embodiment are the same as in the first embodiment but the size of the matrix of the core layer has to be at least 20 μm. If the size of the matrix is less than 20 μm, the scattering coefficient may increase.

The shell layer formed on the core layer may include phosphors and/or quantum dots, with the size of the phosphors and/or quantum dots being 100 nm or less. If the size of the phosphors and/or quantum dots exceeds 100 nm, package efficiency may decrease due to light scattering. Like the first embodiment, the composite of the second embodiment may be an organic dye-linked organic-inorganic nanocomposite.

Further, the shell layer may be 5˜100 Inn thick. If the thickness of the shell layer is less than 5 nm, the phosphors or the quantum dots are not applied in a sufficient amount, making it impossible to obtain sufficient light emission. In contrast, if the thickness thereof exceeds 100 nm, light scattering may increase due to the thickness of the phosphors or quantum dots, undesirably increasing loss due to light scattering.

The composite of the second embodiment may be manufactured using a typical method of preparing a core/shell composite, and is preferably obtained by coating the surface of microbeads with phosphors or quantum dots.

According to the present invention, a phosphor-matrix composite powder can be usefully employed in LEDs, illuminations and displays to which a composite serving as a light source for absorbing blue or near-ultraviolet light to emit visible light is applied.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A phosphor-matrix composite powder for minimizing light scattering comprising:
a matrix; and
a plurality of phosphors or quantum dots having a size of 100 nm or less dispersed in the matrix;
wherein the composite size is 20 μm or more;
Wherein the composite surface root-mean-square-roughness (R_{q}) of composite is 50 nm or more; and
wherein the composite is used as a light source for absorbing blue or near-ultraviolet light to emit visible light.

2. A phosphor-matrix composite powder having a core layer and a shell layer for minimizing light scattering, wherein the core layer comprises a matrix having a size of 20 μm or more and the shell layer comprises a plurality of phosphors or quantum dots having a size of 100 nm or less;
wherein the composite size is 20 μm or more;
wherein the composite surface root-mean-square-roughness (R_{q}) of composite is 50 nm or more;
wherein the composite is used as a light source for absorbing blue or near-ultraviolet light to emit visible light.

3. The phosphor-matrix composite powder of claim 1, wherein the composite powder has a size of 30˜500 μm.

4. The phosphor-matrix composite powder of claim 1, wherein the composite powder has a spherical shape, a cylindrical shape or a cubic shape.

5. The phosphor-matrix composite powder of claim 1, wherein the phosphors comprise at least one selected from the group consisting of (YₓGd₁₋ₓ)₃(Al_{y}Ga_{1-y})₅O₁₂:Ce (x=0.0˜3.0, y=0.0˜5.0), (TbₓGd₁₋ₓ)₃(Al_{y}Ga_{1-y})₅O₁₂:Ce (x=0.0˜3.0, y=0.0˜5.0), Mg₃(YₓGd₁₋ₓ)₂Ge₃O₁₂:Ce (x=0.0˜2.0), CaSc₂O₄:Ce, Ca₃Sc₂Si₃O₁₂:Ce, (Srₓ,Ba_{y},Ca_{z})MgSi₂O₆:Eu,Mn (x, y, z=0.0˜1.0, x+y+z=1.0), (Srₓ,Ba_{y},Ca_{z})₃MgSi₂O₈:Eu,Mn (x, y, z=0.0˜3.0, x+y+z=3.0), (Srₓ,Ba_{y},Ca_{z})MgSiO₄:Eu,Mn (x, y, z=0.0˜1.0, x+y+z=1.0), Lu₂CaMg₂(Siₓ,Ge₁₋ₓ)₃O₁₂:Ce (x=0.0˜3.0), (Srₓ,Ba_{y},Ca_{z})₂SiO₄:Eu (x, y, z=0.0˜2.0, x+y+z=2.0), (Srₓ,Ba_{y},Ca_{z})₃SiO₅:Eu (x, y, z=0.0˜3.0, x+y+z=3.0), (Srₓ,Ba_{y},Ca_{z})₃SiO₅:Ce,Li (x, y, z=0.0˜3.0, x+y+z=3.0), Li₂SrSiO₄:Eu, LaSr₂AlO₅:Ce, Ca₂BO₃Cl:Eu, Y₃Mg₂AlSi₂O₁₂:Ce, BaMgAl₁₀O₁₇:Eu, Sr₂BaAlO₄F:Ce, (Srₓ,Ba_{y},Ca_{z})Ga₂S₄:Eu (x, y, z=0.0˜1.0, x+y+z=1.0), Ba₂ZnS₃:Ce,Eu, Ca₂SiS₄:Eu, Ca α-SiALON:Yb, Ca α-SiALON:Eu, α-SiALON:Yb, α-SiALON:Eu, Ca—Li-α-SiALON:Eu, β-SiALON:Eu, γ-AlON:Mn, γ-AlON:Mn,Mg, (Srₓ,Ba_{y},Ca_{z})₂Si₅N₈:Eu (x, y, z=0.0˜2.0, x+y+z=2.0), (Srₓ,Ba_{y},Ca_{z})Si₂O₂N₂:Eu (x, y, z=0.0˜1.0, x+y+z=1.0), CaₓAl₁₂(ON)₁₆:Eu, Ba₃Si₆O₁₂N₂:Eu, (Ba₁₋ₓSrₓ)_{Y}Si₄O₇:Eu (x=0.0˜1.0), (Ca₁₋ₓSrₓ)AlSiN₃:Eu (x=0.0˜1.0), and AlN:Eu.

6. The phosphor-matrix composite powder of claim 1, wherein the composite powder is transparent.

7. The phosphor-matrix composite powder of claim 1, wherein a mixing ratio of the matrix and the phosphors is 99.99:0.01˜50:50 by mass.

8. The phosphor-matrix composite powder of claim 1, wherein the matrix comprises a transparent material having a high refractive index.

9. The phosphor-matrix composite powder of claim 1, wherein the matrix is alumina, silicate, TiO₂, HfO₂, CeO₂, Y₂O₃, Gd₂O₃ or a silicone-based resin.

10. The phosphor-matrix composite powder of claim 1, wherein the quantum dots comprise at least one selected from the group consisting of CdSe/ZnS, CuInS₂/ZnS, Cu₂In₅S₈/ZnS, AgInS₂/ZnS, Ag₂In₅S₈/ZnS, and InP/ZnS.

11. The phosphor-matrix composite powder of claim 1, wherein the composite is an organic dye-linked organic-inorganic nanocomposite.

12. The phosphor-matrix composite powder of claim 11, wherein the organic dye-linked organic-inorganic nanocomposite is an organic dye-bridged organic-inorganic nanocomposite.

13. The phosphor-matrix composite powder of claim 12, wherein the organic dye-bridged organic-inorganic nanocomposite is prepared by subjecting a red dye or green dye-bridged alkoxysilane-based nanocomposite to a sol-gel reaction to prepare an oligosiloxane composite which then undergoes a condensation reaction.

14. The phosphor-matrix composite powder of claim 2, wherein the shell layer has a thickness of 5˜100 nm.

15. An LED structure comprising a blue or near-ultraviolet LED and the composite of claim 1 bonded thereto.

16. The phosphor-matrix composite powder of claim 2, wherein the composite powder has a size of 30˜500 μm.

17. The phosphor-matrix composite powder of claim 2, wherein the composite powder has a spherical shape, a cylindrical shape or a cubic shape.

18. The phosphor-matrix composite powder of claim 2, wherein the phosphors comprise at least one selected from the group consisting of (YxGd1−x)3(AlyGa1−y)5O12:Ce (x=0.0˜3.0, y=0.0˜5.0), (TbxGd1−x)3(AlyGa1−y)5O12:Ce (x=0.0˜3.0, y=0.0˜5.0), Mg3(YxGd1−x)2Ge3O12:Ce (x=0.0˜2.0), CaSc2O4:Ce, Ca3Sc2Si3O12:Ce, (Srx,Bay,Caz)MgSi2O6:Eu,Mn (x, y, z=0.0˜0, x+y+z=1.0), (Srx,Bay,Caz)3MgSi2O8:Eu,Mn (x, y, z=0.0˜3.0, x+y+z=3.0), (Srx,Bay,Caz)MgSiO4:Eu,Mn (x, y, z=0.0˜1.0, x+y+z=1.0), Lu2CaMg2(Six,Ge1−x)3O12:Ce (x=0.0˜3.0), (Srx,Bay,Caz)2SiO4:Eu (x, y, z=0.0˜2.0, x+y+z=2.0), (Srx,Bay,Caz)3SiO5:Eu (x, y, z=0.0˜3.0, x+y+z=3.0), (Srx,Bay,Caz)3SiO5:Ce,Li (x, y, z=0.0˜3.0, x+y+z=3.0), Li2SrSiO4:Eu, LaSr2AlO5:Ce, Ca2BO3Cl:Eu, Y3Mg2AlSi2O12:Ce, BaMgAl10O17:Eu, Sr2BaAlO4F:Ce, (Srx,Bay,Caz)Ga2S4:Eu (x, y, z=0.0˜1.0, x+y+z=1.0), Ba2ZnS3:Ce,Eu, Ca2SiS4:Eu, Ca(—SiALON:Yb, Ca(—SiALON:Eu, (—SiALON:Yb, (—SiALON:Eu, Ca—Li-(—SiALON:Eu, (—SiALON:Eu, (—AlON:Mn, (—AlON:Mn,Mg, (Srx,Bay,Caz)2Si5N8:Eu (x, y, z=0.0˜2.0, x+y+z=2.0), (Srx,Bay,Caz)Si2O2N2:Eu (x, y, z=0.0˜1.0, x+y+z=1.0), CaxAl12(ON)16:Eu, Ba3Si6O12N2:Eu, (Ba1−xSrx)YSi4O7:Eu (x=0.0˜1.0), (Ca1−xSrx)AlSiN3:Eu (x=0.0˜1.0), and AlN:Eu.

19. The phosphor-matrix composite powder of claim 2, wherein the composite powder is transparent.

20. The phosphor-matrix composite powder of claim 2, wherein a mixing ratio of the matrix and the phosphors is 99.99:0.01˜50:50 by mass.

21. The phosphor-matrix composite powder of claim 2, wherein the matrix comprises a transparent material having a high refractive index.

22. The phosphor-matrix composite powder of claim 2, wherein the matrix is alumina, silicate, TiO₂, HfO₂, CeO₂, Y₂O₃, Gd₂O₃ or a silicone-based resin.

23. The phosphor-matrix composite powder of claim 2, wherein the quantum dots comprise at least one selected from the group consisting of CdSe/ZnS, CuInS₂/ZnS, Cu₂In₅S₈/ZnS, AgInS₂/ZnS, Ag₂In₅S₈/ZnS, and InP/ZnS.

24. The phosphor-matrix composite powder of claim 2, wherein the composite is an organic dye-linked organic-inorganic nanocomposite.

25. The phosphor-matrix composite powder of claim 24, wherein the organic dye-linked organic-inorganic nanocomposite is an organic dye-bridged organic-inorganic nanocomposite.

26. The phosphor-matrix composite powder of claim 2, wherein the organic dye-bridged organic-inorganic nanocomposite is prepared by subjecting a red dye or green dye-bridged alkoxysilane-based nanocomposite to a sol-gel reaction to prepare an oligosiloxane composite which then undergoes a condensation reaction.

27. The LED structure, comprising a blue or near-ultraviolet LED and the composite of claim 2 bonded thereto.
